(19) United States
(12) Patent Application Publication
(10) Pub. No.: US 2025/0125807 A1
(43) Pub. Date: Apr. 17, 2025

(54) DLL CIRCUIT AND LIGHT-EMITTING DEVICE

(71) Applicant: SONY SEMICONDUCTOR SOLUTIONS CORPORATION, KANAGAWA (JP)

(72) Inventors: MANABU KOSUGE, KANAGAWA (JP); MIHO AKAGI, KANAGAWA (JP)

(21) Appl. No.: 18/686,537

(22) PCT Filed: Mar. 23, 2022
(86) PCT No.: PCT/JP2022/013544

§ 371 Date: Feb. 26, 2024

(30) Foreign Application Priority Data
Sep. 15, 2021 (JP) 2021-149983

(51) Int. Cl. H03L 7/081; H03L 7/089; H05B 47/10

(52) U.S. Cl. CPC H03L 7/0816; H03L 7/0891; H05B 47/10

(57) ABSTRACT

A DLL circuit includes: a first delay line having a first delay buffer that provides a delay corresponding to a control voltage to an input clock signal and configured to output an output clock signal via the first delay buffer; a control voltage generation unit having a phase comparator that compares phases of the input clock signal and the output clock signal, and configured to generate the control voltage based on an output of the phase comparator; a charge storage unit configured to store charges for holding the control voltage; and a drive control unit configured to output a drive control signal for stopping an operation of the phase comparator based on a determination result regarding a delay-locked state.

### TECHNICAL FIELD

The present technology relates to the technical field of DLL circuits and light-emitting devices that add a predetermined amount of delay to an input signal.

### BACKGROUND ART

In devices that require high-speed operation, it is necessary to perform timing control with high precision, and some devices are equipped with a DLL (Delay Locked Loop) circuit as a circuit configuration for this purpose.

DLL circuits are required to save power in consideration of installation in portable terminals such as mobile phones.

PTL 1 below discloses a technique for suppressing power consumption when a clock synchronization circuit is in an inactive state by including a control circuit that activates a clock generation circuit for a specific period.

### CITATION LIST

### Patent Literature

[PTL 1]
JP 2002-184864A

### SUMMARY

### Technical Problem

However, in the method of PTL 1, each part of the DLL circuit needs to continue operating in the delay-locked state where the delay amount is controlled to a predetermined amount, and it is difficult to say that sufficient power saving is achieved.

The present technology has been developed in view of such problems, and an object thereof is to reduce the power consumption of a DLL circuit.

### Solution to Problem

A DLL circuit according to the present technology includes: a first delay line having a first delay buffer that provides a delay corresponding to a control voltage to an input clock signal and configured to output an output clock signal via the first delay buffer; a control voltage generation unit having a phase comparator that compares phases of the input clock signal and the output clock signal, and configured to generate the control voltage based on an output of the phase comparator; a charge storage unit configured to store charges for holding the control voltage; and a drive control unit configured to output a drive control signal for stopping an operation of the phase comparator based on a determination result regarding a delay-locked state.

As a result, the control voltage applied to the delay buffer is held in the delay-locked state, and the operation of the phase comparator is stopped.

### BRIEF DESCRIPTION OF DRAWINGS

FIG. 1 is a diagram showing a configuration example of a DLL circuit in a first embodiment.

FIG. 2 is a diagram showing a configuration example of a control voltage generation unit.

FIG. 3 is a diagram showing a configuration example of a master delay line.

FIG. 4 is a diagram showing a configuration example of a delay buffer.

FIG. 5 is a diagram showing a configuration example of a slave delay line.

FIG. 6 is a diagram showing a configuration example of the DLL circuit according to a first embodiment, and shows the DLL circuit in a dynamic hold state.

FIG. 7 is a diagram for explaining state transition of a DLL circuit.

FIG. 8 is a diagram showing a configuration example of a DLL circuit according to a second embodiment.

FIG. 9 is a diagram showing a configuration example of a DLL circuit according to the second embodiment, and shows the DLL circuit in a dynamic hold state.

FIG. 10 is a diagram showing a configuration example of a DLL circuit according to a third embodiment.

FIG. 11 is a diagram illustrating a configuration example of the DLL circuit according to the third embodiment, and shows the DLL circuit in a dynamic hold state.

FIG. 12 is a diagram showing a configuration example of a DLL circuit in a fourth embodiment.

FIG. 13 is a diagram showing a configuration example of a DLL circuit according to a fourth embodiment, and shows the DLL circuit in a dynamic hold state.

FIG. 14 is a diagram showing a configuration example of a light emission pulse generation unit included in a light-emitting device.

FIG. 15 is a diagram for explaining the relationship between an input data signal, an output data signal, and an output signal of an AND circuit.

### DESCRIPTION OF EMBODIMENTS

Hereinafter, embodiments according to the present technology will be described in the following order with reference to the accompanying drawings.
<1. System configuration>
<2. Master delay line configuration>
<3. Slave delay line configuration>
<4. Power saving>
<5. Second embodiment>
<6. Third embodiment>
<7. Fourth embodiment>
<8. Application example>
<9. Summary>
<10. Present technology>

### 1. System Configuration

A DLL (Delay Locked Loop) circuit 1 according to a first embodiment will be explained with reference to the attached drawings.

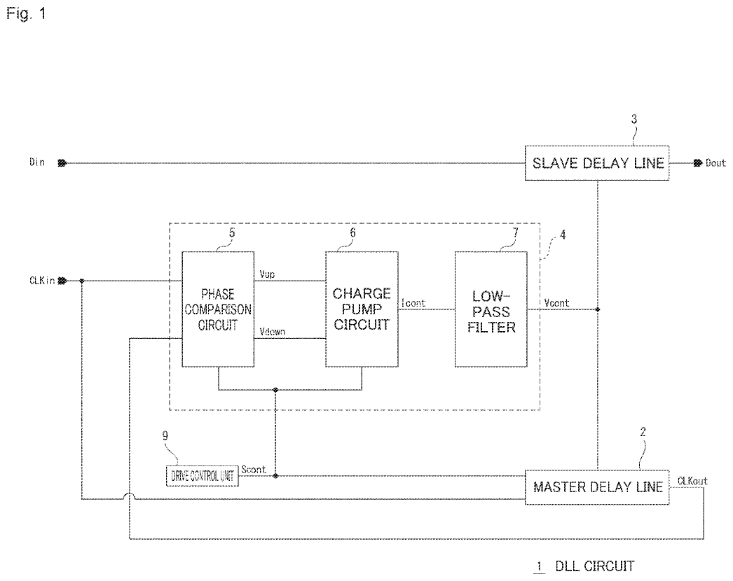

FIG. 1 shows a configuration example of the DLL circuit 1 in the present embodiment. The DLL circuit 1 includes a master delay line 2, a slave delay line 3, and a control voltage generation unit 4.

The master delay line 2 provides a delay corresponding to a control voltage Vcont to an input clock signal CLKin to generate an output clock signal CLKout. Specifically, the master delay line 2 is configured by connecting in series a plurality of delay buffers DB that add delay to the input clock signal CLKin. Then, the master delay line 2 propagates the input clock signal CLKin via a delay buffer DB (described later) and outputs it as an output clock signal CLKout.

The control voltage generation unit 4 generates the control voltage Vcont based on a phase difference between the input clock signal CLKin and the output clock signal CLKout from the master delay line 2.

The control voltage generation unit 4 controls the voltage value of the control voltage Vcont so that the delay provided to the input clock signal CLKin by the delay buffer DB group of the master delay line 2 is one cycle (2π), that is, so that the steady-state phase error is eliminated.

A state in which the steady-state phase error is eliminated or a state in which the steady-state phase error is less than a predetermined value is referred to as a “delay-locked state.” Further, the delay-locked state can also be referred to as a state in which the difference between the voltage value of the control voltage Vcont and the target voltage value (voltage value V1) is less than a predetermined value.

The control voltage generation unit 4 includes a phase comparison circuit 5, a charge pump circuit 6, and a low-pass filter 7.

The phase comparison circuit 5 detects a phase difference between the input clock signal CLKin and the output clock signal CLKout, and generates control signals Vup and Vdown for manipulating the phase of the output clock signal CLKout. The charge pump circuit 6 generates a control current Icont according to the control signals Vup and Vdown. The low-pass filter 7 functions as a loop filter in a feedback loop that constitutes the DLL circuit 1, and generates the control voltage Vcont based on the control current Icont.

Here, the operation of the control voltage generation unit 4 will be explained.

First, the output clock signal CLKout obtained via the master delay line 2 is a signal obtained by adding a delay caused by the delay buffer DB forming the master delay line 2 to the input clock signal CLKin.

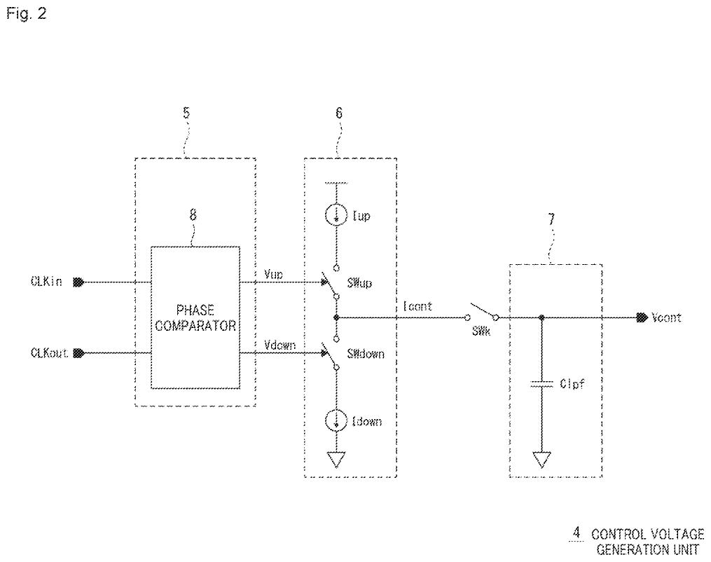

As shown in FIG. 2, the phase comparison circuit 5 of the control voltage generation unit 4 uses a phase comparator 8 to compare the phases of the input clock signal CLKin and the output clock signal CLKout.

The phase comparator 8 outputs the control signals Vup and Vdown to the subsequent charge pump circuit 6 according to the result of the phase comparison.

Specifically, when the phase of the output clock signal CLKout is too delayed with respect to the input clock signal CLKin, that is, when the delay provided to the input clock signal CLKin is large, the phase comparator 8 outputs the control signal Vup to the subsequent charge pump circuit 6.

On the other hand, when the phase delay is insufficient, that is, when the delay provided to the input clock signal CLKin is small, the phase comparator 8 outputs the control signal Vdown to the subsequent charge pump circuit 6.

Note that, depending on the circuit configuration of the subsequent stage, the control signal Vdown may be output when the phase is too delayed, and the control signal Vin may be output when the phase delay is insufficient.

Further, when the phase delay of the output clock signal CLKout with respect to the input clock signal CLKin is appropriate, that is, when the steady-state phase error is eliminated, the phase comparator 8 performs control so that the time for outputting the control signal Vup and the time for outputting the control signal Vdopwn to the subsequent charge pump circuit 6 are approximately the same. For example, the control signals Vup and Vdown may have the same pulse width.

In the charge pump circuit 6, for example, a constant current source lup on the power supply side and a constant current source Idown on the ground side are connected in series, and two switches SWup and SWdown are connected in series between the constant current source Iup and the constant current source Idown.

The switches SWup and SWdown are configured of, for example, MOSFETs (Metal Oxide Semiconductor Field Effect Transistors).

The switch SWup on the power supply side is controlled to be turned on when the control signal Vup is output, and is controlled to be turned off when the control signal Vdown is output.

On the contrary, the switch SWdown on the ground side is controlled to be turned on when the control signal Vdown is output, and is controlled to be turned off when the control signal Vup is output.

Note that, if the delay time of the output clock signal CLKout is appropriate, the on/off control of each switch may be performed so that the ON times of the switch SWup and the switch SWdown are approximately the same, or both the switch SWup and the switch SWdown may be controlled to be turned off.

A switch SWk is connected between the connection point between the switch SWup and the switch SWdown and the low-pass filter 7.

The switch SWk is controlled to be turned on until the delay time of the output clock signal CLKout becomes appropriate, and is controlled to be turned off when the delay time becomes appropriate. The details will be described later.

The charge pump circuit 6 supplies the control current Icont to the low-pass filter 7 according to the control signal Vup or Vdown.

Specifically, while the control signal Vup is input, the control current Icont is controlled so that a current flows from the constant current source Iup to the low-pass filter 7 via the switch SWup and the switch SWk.

On the other hand, while the control signal Vdown is input, the control current Icont is controlled so that a current flows from the low-pass filter 7 to the constant current source Idown via the switch SWk and the switch SWdown.

The low-pass filter 7 includes a capacitor Clpf. The control current Icont output from the charge pump circuit 6 is smoothed by the low-pass filter 7. The output of the charge pump circuit 6 is the control voltage Vcont having a voltage value corresponding to the current value of the control current Icont.

The control voltage Vcont is input to the master delay line 2.

In this way, the control voltage Vcont is adjusted according to the delay time of the output clock signal CLKout output from the master delay line 2 with respect to the input clock signal CLKin, and is determined to be a predetermined voltage value when the delay time becomes appropriate. At this time, the delay added to the input clock signal CLKin is also determined to be a constant delay amount.

The control voltage Vcont adjusted to a predetermined voltage value is input to the slave delay line 3.

The slave delay line 3 includes a plurality of delay buffers DB having the same configuration as the master delay line 2 connected in series.

By inputting the adjusted control voltage Vcont to each delay buffer DB, the delays provided in one delay buffer DB can be matched between the master delay line 2 and the slave delay line 3.

Note that the number of stages of the delay buffers DB included in the master delay line 2 and the number of stages of the delay buffers DB included in the slave delay line 3 may be different.

The number of stages of the delay buffers DB of the master delay line 2 is determined by the step width of the delay time. For example, if the delay time is equivalent to ½π in terms of phase, the master delay line 2 includes four stages of the delay buffers DB.

Note that, when a dummy delay buffer DB is provided at the first stage or the last stage of the master delay line 2, the master delay line 2 may include five or more stages of the delay buffers DB.

On the other hand, the number of stages of the delay buffers DB of the slave delay line 3 is determined according to the desired delay time to be provided.

For example, if one delay buffer DB is adjusted to provide a delay of 10 ps (picoseconds) and the slave delay line 3 is configured to provide a delay of 50 ps, the number of stages of the delay buffers DB in the slave delay line 3 is set to “5”.

Note that, when a dummy delay buffer DB is provided at the first stage or the last stage of the slave delay line 3, the slave delay line 3 may include six or more stages of the delay buffers DB.

The slave delay line 3 outputs an output data signal Dout obtained by delaying the input data signal Din by a predetermined time.

The DLL circuit 1 has a function of stopping the operation of a predetermined portion of the DLL circuit 1 in order to save power. Specifically, the DLL circuit 1 includes a drive control unit 9 (see FIG. 1).

The drive control unit 9 is capable of outputting a high level signal (H signal) for operating the circuit and a low level signal (L signal) for stopping the operation of the circuit.

In the example shown in FIG. 1, a drive control signal Scont output from the drive control unit 9 is input to the phase comparison circuit 5, the charge pump circuit 6, and the master delay line 2. Therefore, the drive control unit 9 is capable of controlling the stopping of the drive of the phase comparison circuit 5, the charge pump circuit 6, and the master delay line 2.

For example, the drive control unit 9 outputs an L signal as the drive control signal Scont in response to elimination of the steady-state phase error in the phase comparator 8.

The state in which the steady-state phase error is eliminated may be detected by detecting that the control voltage Vcont has changed to a predetermined value, or by detecting that the change in the control voltage Vcont has become small. Alternatively, the state may be detected by detecting that the ratio of the time for outputting the control signal Vup and the time for outputting the control signal Vdopwn has become substantially the same. Alternatively, the control signals Vup and Vdown output by the phase comparator 8 may be configured so that both signals become L signals in a state where the steady-state phase error is eliminated, and a state that the control signals Vup and Vdown both become L signals may be detected.

Alternatively, the drive control unit 9 may output an L signal as the drive control signal Scont, assuming that the adjustment of Vcont has been completed when a predetermined time has elapsed since the adjustment of the control voltage Vcont (delay lock control) was started.

Various signals are input to the drive control unit 9 for detecting a state in which the steady-state phase error is eliminated.

Note that the drive control unit 9 may have the function of the switch SWk shown in FIG. 2. That is, the switch SWk is conceptually shown in FIG. 2, and it is not necessary to provide a switching element actually.

For example, the drive control unit 9 may be configured to be capable of controlling the constant current sources lup and Idown to be turned off, and instead of turning off the switch SWk, all the switches SWup and SWdown and all the constant current sources lup and Idown may be controlled to be turned off.

### 2. Master Delay Line Configuration

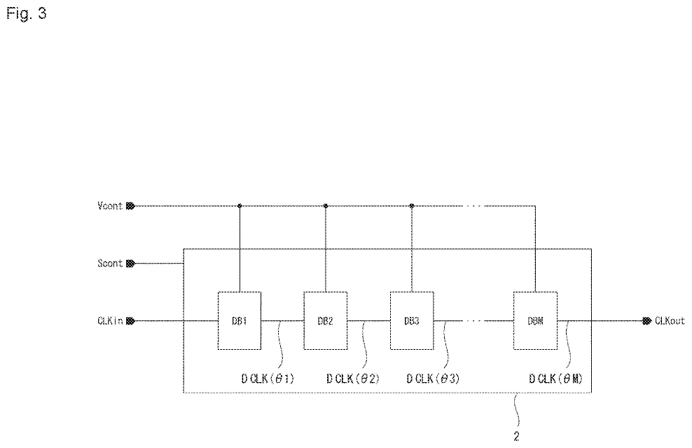

A configuration example of the master delay line 2 is shown in FIG. 3.

The master delay line 2 is configured to include a plurality of delay buffers DB (DB1 to DBM).

The drive control signal Scont output from the drive control unit 9 is input to the master delay line 2. The master delay line 2 stops operating when the drive control signal Scont is an L signal.

The control voltage Vcont is input to each delay buffer DB.

The delay buffer DB has a variable delay time depending on the voltage value of the control voltage Vcont. Specifically, increasing the voltage value shortens the delay time, and decreasing the voltage value increases the delay time.

The voltage value of the control voltage Vcont input to the delay buffer DB is adjusted by the phase comparison circuit 5 and the charge pump circuit 6 until the total delay time provided in the master delay line 2 becomes one cycle of the input clock signal CLKin.

The input clock signal CLKin is input to the delay buffer DB1, which is the first stage delay buffer DB of the master delay line 2. The delay buffer DB1 outputs a signal obtained by delaying the input clock signal CLKin by a predetermined time as a delayed clock signal DCLK (θ1).

The delayed clock signal DCLK (θ1) is input to the next stage delay buffer DB2.

The delay buffer DB2 outputs a delayed clock signal DCLK (θ2) which is obtained by further delaying the delayed clock signal DCLK (θ1) by a predetermined time.

The delay buffer DBM at the last stage of the master delay line 2 outputs a delayed clock signal DCLK (θM). The delayed clock signal DCLK (θM) is the output clock signal CLKout output from the master delay line 2.

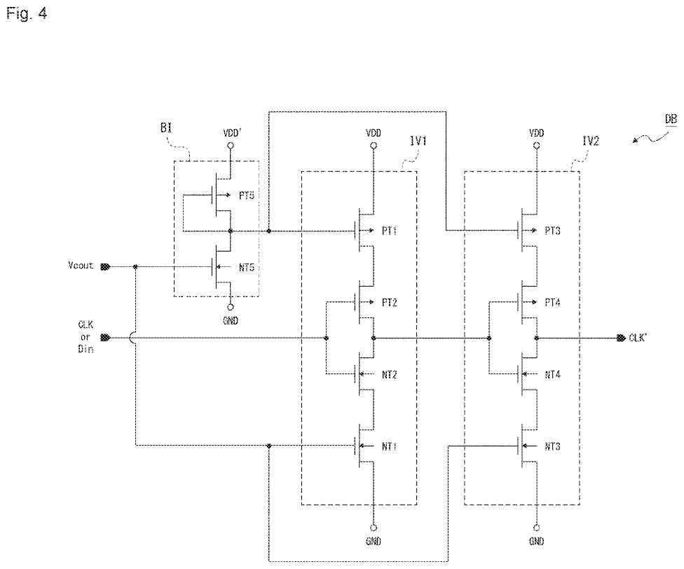

A configuration example of the delay buffer DB of the master delay line 2 is shown in FIG. 4.

The delay buffer DB includes a BIAS circuit and inverters IV1 and IV2.

The inverter IV1 includes two PMOS transistors PT1 and PT2 which are P-channel MOSFETs, and two NMOS transistors NT1 and NT2 which are N-channel MOSFETs.

Similarly, the inverter IV2 includes two PMOS transistors PT3 and PT4 which are P-channel MOSFETs, and two NMOS transistors NT3 and NT4 which are N-channel MOSFETs. Since the inverters IV1 and IV2 have similar configurations, the inverter IVI will be mainly described.

A power supply voltage VDD is applied to the source terminal of the PMOS transistor PT1.

The drain terminal of the PMOS transistor PT1 is connected to the source terminal of the PMOS transistor PT2.

The drain terminal of the PMOS transistor PT2 is connected to the drain terminal of the NMOS transistor NT2.

The source terminal of the NMOS transistor NT2 is connected to the drain terminal of the NMOS transistor NT1.

A ground voltage GND is applied to the source terminal of the NMOS transistor NT1.

The control voltage Vcont is inverted by the BIAS circuit BI and applied to the gate terminal of the PMOS transistor PT1.

The BIAS circuit BI includes a PMOS transistor PT5 which is a P-channel MOSFET and an NMOS transistor NT5 which is an N-channel MOSFET, and outputs a signal obtained by inverting Vcont, which is an analog signal.

A power supply voltage VDD′ is applied to the source terminal of the PMOS transistor PT5.

The power supply voltage VDD′ may be the same voltage as the power supply voltage VDD, or may be a different voltage.

The drain terminal of the PMOS transistor PT5 is connected to the drain terminal of the NMOS transistor NT5 and the gate terminal of the PMOS transistor PT5.

A ground voltage GND is applied to the source terminal of the NMOS transistor NT5.

As a result, a signal obtained by inverting the input signal of the BIAS circuit, that is, a signal obtained by inverting the control voltage Vcont is output at the drain terminal of the PMOS transistor PT5 and the drain terminal of the NMOS transistor NT5.

A control voltage Vcont is applied to the gate terminal of the NMOS transistor NT1.

A signal to be subjected to delay control is applied to each gate terminal of the PMOS transistor PT2 and the NMOS transistor NT2. An input clock signal CLKin is applied to the master delay line 2.

In the slave delay line 3, which will be described later, an input data signal Din is applied to each gate terminal of the PMOS transistor PT2 and the NMOS transistor NT2 as a signal to be subjected to delay control.

Note that the signal output from the inverter IVI is applied to each gate terminal of the PMOS transistor PT4 and the NMOS transistor NT4 of the inverter IV2.

The current value of the PMOS transistor PT1 and the NMOS transistor NT1 is limited by the control voltage Vcont. Therefore, the PMOS transistor PT2 and the NMOS transistor NT2 function as an inverter that adds a delay to the input clock signal CLKin.

The inverter IV2 restores the signal inverted by the inverter IV1 and adds a delay to the input signal. That is, in the delay buffer DB, a delay is added by the inverter IVI and the inverter IV2.

In this way, the delay buffer DB adds a delay to the input signal according to the voltage value of the control voltage Vcont.

### 3. Slave Delay Line Configuration

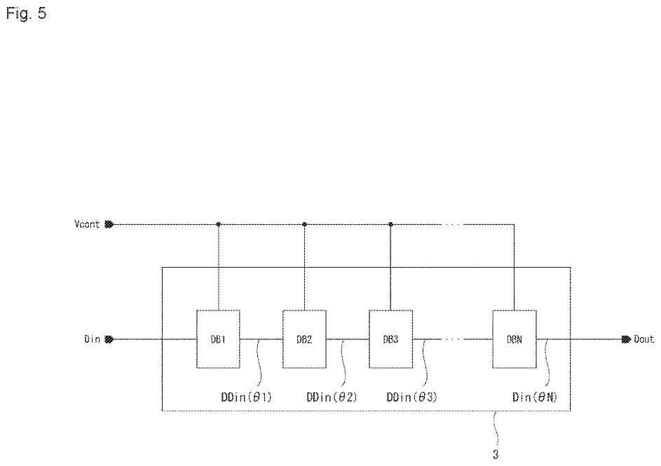

FIG. 5 shows the configuration of the slave delay line 3.

The slave delay line 3 has substantially the same configuration as the master delay line 2. Specifically, the slave delay line 3 is configured to include a plurality of delay buffers DB (DB1 to DBN).

The number of delay buffers DB is M for the master delay line 2, while N for the slave delay line 3.

M and N may be the same number, or may be different numbers.

A control voltage Vcont is input to each delay buffer DB.

The input data signal Din is input to the delay buffer DB1, which is the first stage delay buffer DB of the slave delay line 3. The delay buffer DB1 outputs a signal obtained by delaying the input data signal Din by a predetermined time as a delayed input data signal DDin (θ1).

The delay buffer DBN at the last stage of the slave delay line 3 outputs a delayed input data signal DDin (θN). The delayed input data signal DDin (ON) is used as the output data signal Dout output from the slave delay line 3.

The configuration of the delay buffer DB included in the slave delay line 3 is the same as the configuration shown in FIG. 4 described above, and therefore, the description thereof will be omitted.

Note that the drive control signal Scont is not input to the slave delay line 3.

### 4. Power Saving

In a general DLL circuit, in order to maintain the state in which the delay time of the delay provided in each delay buffer DB is adjusted to a predetermined value, that is, the so-called delay-locked state in which the steady-state phase error is eliminated and the input clock signal CLKin and the output clock signal CLKout are synchronized, the operating states of the phase comparison circuit 5, charge pump circuit 6, and the like are maintained.

However, maintaining the operating state of each circuit results in an increase in power consumption.

In this configuration, a “stop period” is provided in which the operations of the phase comparison circuit 5 and the master delay line 2 are stopped.

Specifically, in order to maintain the control voltage Vcont applied to the slave delay line 3 shown in FIG. 2 at the voltage value in the delay-locked state, the switch SWk provided between the charge pump circuit 6 and the low-pass filter 7 is controlled to be turned off.

Further, a switch SWj is provided between the low-pass filter 7 and the master delay line 2, and the control voltage Vcont is applied only to the slave delay line 3 by controlling the switch SWj to be turned off.

As a result, the charge stored in the capacitor Clpf included in the low-pass filter 7 is held, and the control voltage Vcont is maintained. That is, the capacitor Clpf functions as a charge storage unit for maintaining the control voltage Vcont.

Subsequently, an L signal is input from the drive control unit 9 to the phase comparison circuit 5, the charge pump circuit 6, and the master delay line 2 as the drive control signal Scont. In response to this, the phase comparison circuit 5, the charge pump circuit 6, and the master delay line 2 stop operating due to, for example, the supply of drive voltage being stopped.

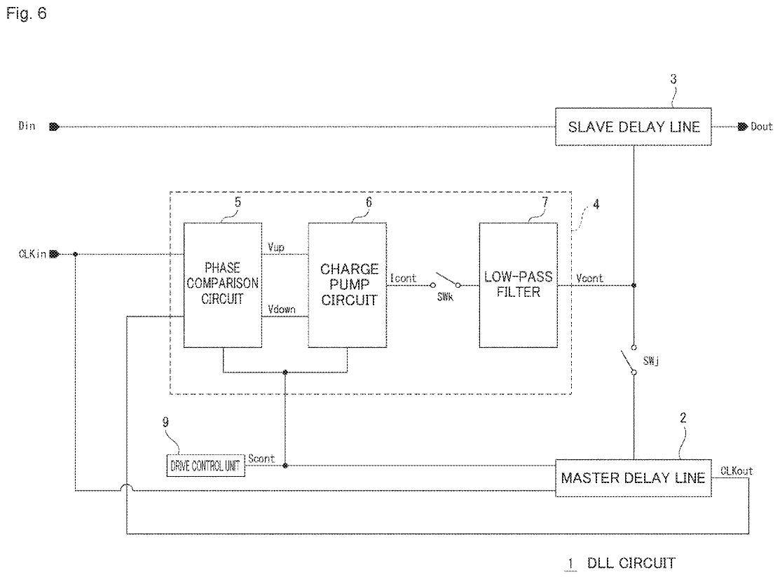

FIG. 6 schematically shows a state in which the operations of the phase comparison circuit 5, the charge pump circuit 6, and the master delay line 2 are stopped.

As shown in the figure, the drive control signal Scont input to the phase comparison circuit 5, the charge pump circuit 6, and the master delay line 2 is set to the L signal, whereby the operation of each circuit is stopped.

By stopping the operations of the phase comparison circuit 5, the charge pump circuit 6, and the master delay line 2, power consumption can be reduced.

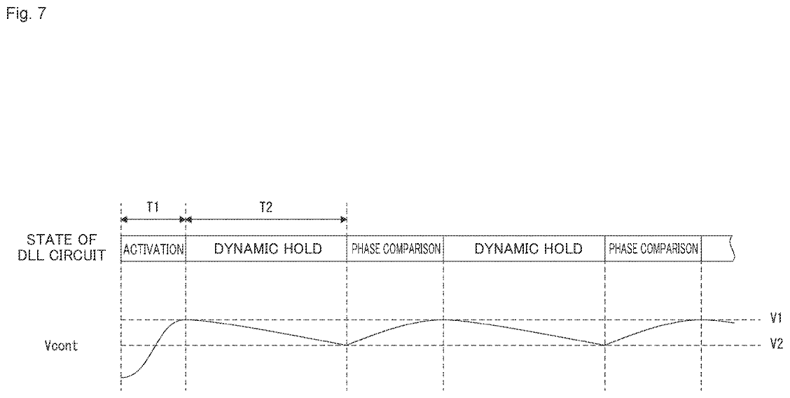

Next, the state transition of the DLL circuit 1 will be explained with reference to FIG. 7.

The DLL circuit 1 takes an “activation” state, a “dynamic hold” state, and a “phase comparison” state. In the “activation” state, the DLL circuit 1 starts delay lock control by starting phase comparison between the input clock signal CLKin and the output clock signal CLKout, and adjusts the control voltage Vcont to the voltage value V1.

The “activation” state continues for a first time T1. The first time T1 may be a variable determined by detecting that the steady-state phase error in the phase comparator 8 is eliminated, or may be a fixed time that can ensure that the steady-state phase error is eliminated.

The state in which the steady-state phase error is eliminated may be detected, for example, as described above, by detecting that the amount of change per unit time in the control voltage Vcont has become less than a predetermined value, or by detecting that the difference between the voltage value of the control voltage Vcont and the target voltage value is less than a predetermined value, or Alternatively, the state may be detected by detecting that the ratio of the time for outputting the control signal Vup and the time for outputting the control signal Vdopwn has become substantially the same.

These processes are executed by the drive control unit 9.

After adjusting the control voltage Vcont, the DLL circuit 1 transitions to a “dynamic hold” state.

The “dynamic hold” state is a state in which the phase difference is exactly one cycle, and is one aspect of the delay-locked state described above. Further, the “dynamic hold” state corresponds to the “stop period” described above.

In the “dynamic hold” state, the operations of the phase comparison circuit 5, the charge pump circuit 6, and the master delay line 2 are stopped, and the state in which the control voltage Vcont is adjusted to the voltage value V1 is maintained.

However, as shown in FIG. 7, the charge stored in the capacitor Clpf gradually decreases due to leakage components and the like. Therefore, the adjusted predetermined delay added by the master delay line 2 cannot be maintained.

Therefore, the DLL circuit 1 transitions to the “phase comparison” state before the predetermined accuracy regarding the delay time can no longer be maintained, that is, before the control voltage Vcont becomes too low.

The transition to the “phase comparison” state is performed according to the establishment of a predetermined condition.

For example, it may be determined that the predetermined condition is established when the second time T2 has elapsed since the transition to the “dynamic hold” state.

Alternatively, it may be determined that the predetermined condition is established when the control voltage Vcont changes to a predetermined value, specifically, when it falls below the voltage value V2.

In the “phase comparison” state, the drive control signal Scont output from the drive control unit 9 is set to an H signal, so that the operation of the phase comparison circuit 5, the charge pump circuit 6, and the master delay line 2 is restarted, and the control voltage Vcont is adjusted again to the voltage value V1 in accordance with the phase comparison result.

The DLL circuit 1 transitions from the “activation” state to the “dynamic hold” state, and then alternately repeats the “phase comparison” state and the “dynamic hold” state to reduce power consumption while ensuring delay time control accuracy.

### 5. Second Embodiment

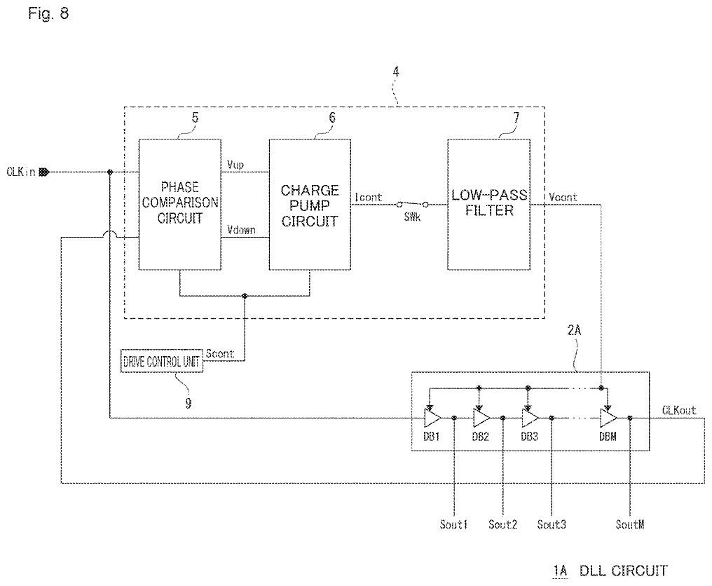

A DLL circuit 1A according to the second embodiment will be described with reference to FIG. 8. The DLL circuit 1A includes a master delay line 2A and a control voltage generation unit 4.

That is, the present embodiment differs from the first embodiment in that it does not include the slave delay line 3.

The configuration of the control voltage generation unit 4 is similar to that of the first embodiment. However, the control voltage Vcont output from the low-pass filter 7 is input only to the master delay line 2A.

FIG. 8 shows the DLL circuit 1A in the “activation” state or the “phase comparison” state. Therefore, the drive control signal Scont output from the drive control unit 9 is an H signal.

The master delay line 2A outputs an output clock signal CLKout obtained by delaying the input clock signal CLKin by one cycle.

Further, the master delay line 2A outputs one or more types of output signals Sout obtained by delaying the input clock signal CLKin.

In the example shown in FIG. 8, the output signal Sout is a plurality of types of signals having different delay times with respect to the input clock signal CLKin.

For example, a signal output from each delay buffer DB of the master delay line 2A is output as the output signal Sout.

In this example, the master delay line 2A has M delay buffers DB1 to DBM, the output signal of the delay buffer DB1 is output as the output signal Sout1, and the output signal of the delay buffer DB2 is output as the output signal Sout2, the output signal of the delay buffer DBM is output as the output signal SoutM.

Here, “N” is a natural number.

The output signal SoutN is the same signal as the output clock signal CLKout.

Each output signal Sout is input to a selector (not shown), for example, so that one output signal Sout can be selected.

That is, the present embodiment is a configuration used when it is desired to use a signal obtained by delaying the input clock signal CLKin.

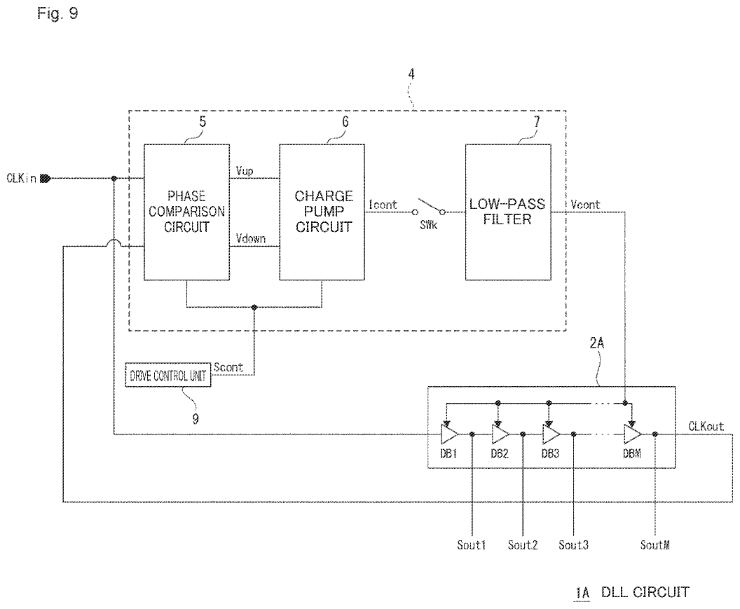

FIG. 9 shows the DLL circuit 1A in the “dynamic hold” state.

As shown in the figure, the switch SWk is controlled to be turned off, and the drive control unit 9 outputs an L signal as the drive control signal Scont, whereby the operations of the phase comparison circuit 5 and the charge pump circuit 6 are stopped.

In this way, the control voltage Vcont applied to the master delay line 2A is maintained at the voltage value in the delay-locked state, and power consumption in the “dynamic hold” state is reduced.

### 6. Third Embodiment

The DLL circuit 1B according to the third embodiment does not include the slave delay line 3 like the DLL circuit 1A according to the second embodiment. Further, unlike the DLL circuit 1A of the second embodiment, it outputs a signal obtained by delaying the input data signal Din, which is different from the input clock signal CLKin.

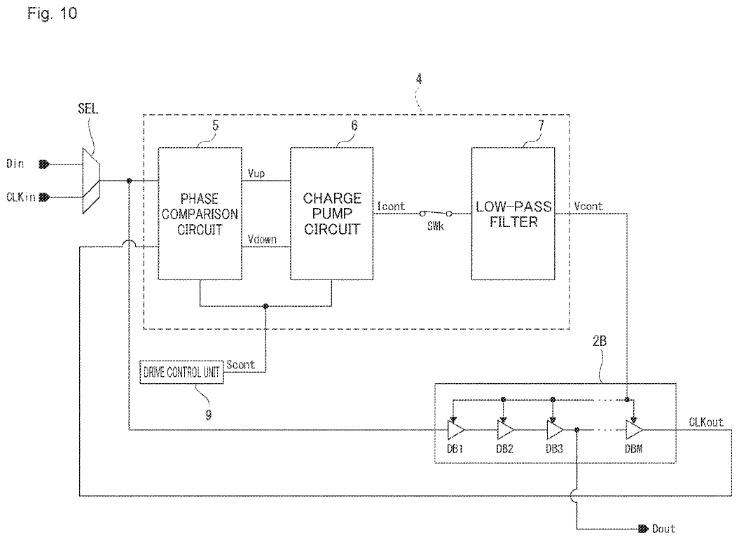

A configuration example of the DLL circuit 1B will be described with reference to FIG. 10.

The DLL circuit 1B includes a selector SEL for switching input signals, a control voltage generation unit 4, and a master delay line 2B.

The configuration of the control voltage generation unit 4 is the same as that of the other embodiments described above, and therefore, the description thereof will be omitted.

FIG. 10 shows the DLL circuit 1B in an “activation” state or a “phase comparison” state. The drive control signal Scont output from the drive control unit 9 is an H signal.

The selector SEL switches between the input clock signal CLKin and the input data signal Din. In the “activation” state and the “phase comparison” state, the input clock signal CLKin is selected by the selector SEL.

In this state, the control voltage Vcont is adjusted by controlling the switch SWk of the control voltage generation unit 4 to be turned on. The master delay line 2B outputs an output clock signal CLKout obtained by delaying the input clock signal CLKin.

The master delay line 2B is configured to include M delay buffers DB1 to DBM, and a signal output from a predetermined delay buffer DB is an output data signal Dout.

Here, “M” is a natural number.

Note that in FIG. 10, the output data signal Dout is output from a position that is downstream of the third stage delay buffer DB3 and ahead of the M-th stage delay buffer DBM. However, the signal output from the first stage delay buffer DB1 may be used as the output data signal Dout, the signal output from the second stage delay buffer DB2 may be used as the output data signal Dout, or the signal output from the M-th stage delay buffer DBM may be used as the output data signal Dout.

Note that the signal output as the output data signal Dout in the “activation” state or the “phase comparison” state is a signal obtained by delaying the input clock signal CLKin.

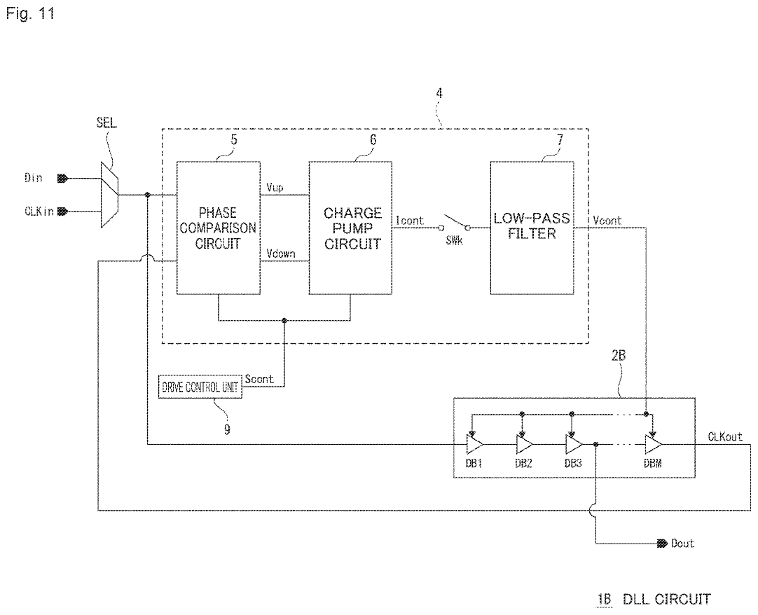

Next, the DLL circuit 1B in the “dynamic hold” state is shown in FIG. 11.

As shown in the figure, by controlling the switch SWk of the control voltage generation unit 4 to be turned off, the control voltage Vcont applied to the master delay line 2B is maintained at the voltage value in the delay-locked state.

Furthermore, the operation of the phase comparison circuit 5 and the charge pump circuit 6 is stopped by setting the drive control signal Scont output from the drive control unit 9 to an L signal.

In this way, the power consumption of the DLL circuit 1B can be reduced.

Further, by selecting the input data signal Din in the selector SEL, a signal obtained by delaying the input data signal Din by a predetermined time is output as the output data signal Dout.

In this way, by providing the selector SEL, it is possible to switch between the signal selected when setting a reference delay time and the signal to which a predetermined delay is provided on the basis of the set delay time.

### 7. Fourth Embodiment

In the third embodiment described above, it is not possible to provide a delay larger than the delay of one cycle of the input clock signal CLKin to the input data signal Din.

In the present embodiment, a configuration that can provide a larger delay to the input data signal Din will be described.

Like the DLL circuit 1B, the DLL circuit 1C includes a selector SEL, a master delay line 2B, and a control voltage generation unit 4. Furthermore, the DLL circuit 1C includes an additional delay line 10.

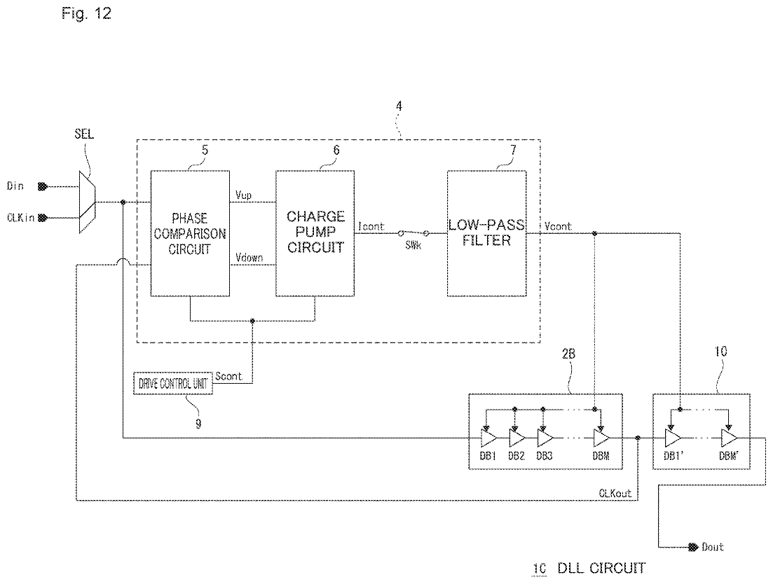

FIG. 12 shows the DLL circuit 1C in the “activation” state or the “phase comparison” state.

Therefore, the drive control signal Scont output from the drive control unit 9 is an H signal.

The additional delay line 10 is provided in series to the subsequent stage of the master delay line 2B, and includes one or more delay buffers DB. In FIG. 12, M′ delay buffers DB1′ to DBM′ are provided.

A control voltage Vcont is applied to each delay buffer DB of the additional delay line 10.

An output clock signal CLKout is output from the connection point between the master delay line 2B and the additional delay line 10.

The configuration of the control voltage generation unit 4 is the same as that of the other embodiments described above, and therefore, the description thereof will be omitted.

The selector SEL switches between the input clock signal CLKin and the input data signal Din. In the “activation” state or the “phase comparison” state, the input clock signal CLKin is selected by the selector SEL.

In this state, the control voltage Vcont is adjusted by controlling the switch SWk of the control voltage generation unit 4 to be turned on. The master delay line 2B outputs an output clock signal CLKout obtained by delaying the input clock signal CLKin.

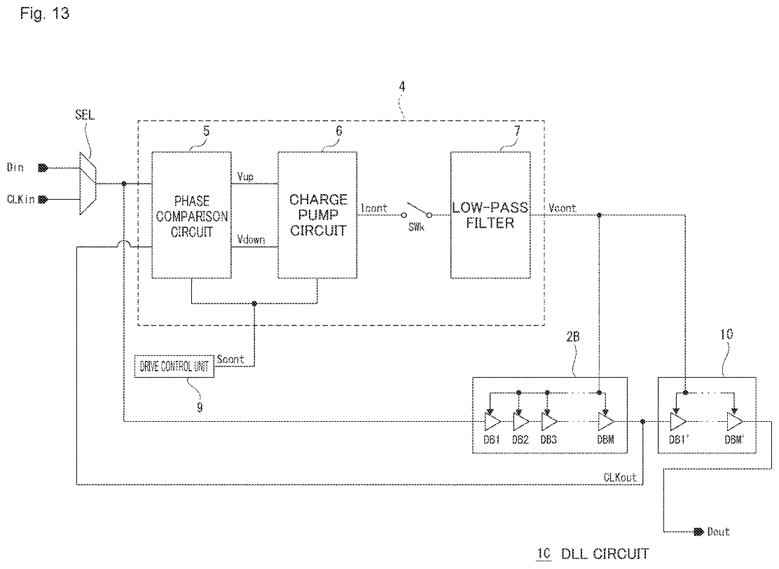

Next, the DLL circuit 1C in the “dynamic hold” state is shown in FIG. 13.

As shown in the figure, the control voltage Vcont applied to the master delay line 2B and the additional delay line 10 is maintained at the voltage value in the delay-locked state by controlling the switch SWk of the control voltage generation unit 4 to be turned off.

Furthermore, the operation of the phase comparison circuit 5 and the charge pump circuit 6 is stopped by setting the drive control signal Scont output from the drive control unit 9 to an L signal.

In this way, the power consumption of the DLL circuit 1C can be reduced.

Further, by selecting the input data signal Din in the selector SEL, a signal obtained by delaying the input data signal Din by a predetermined time is output as the output data signal Dout.

### 8. Application Example

An example in which the above-mentioned DLL circuit 1 (1A, 1B, 1C) is used to generate a light emission pulse signal in the dToF (direct ToF) method, which is a type of ToF (Time of Flight) method that measures distance based on the reflected light of the laser beam irradiated to a target object will be explained.

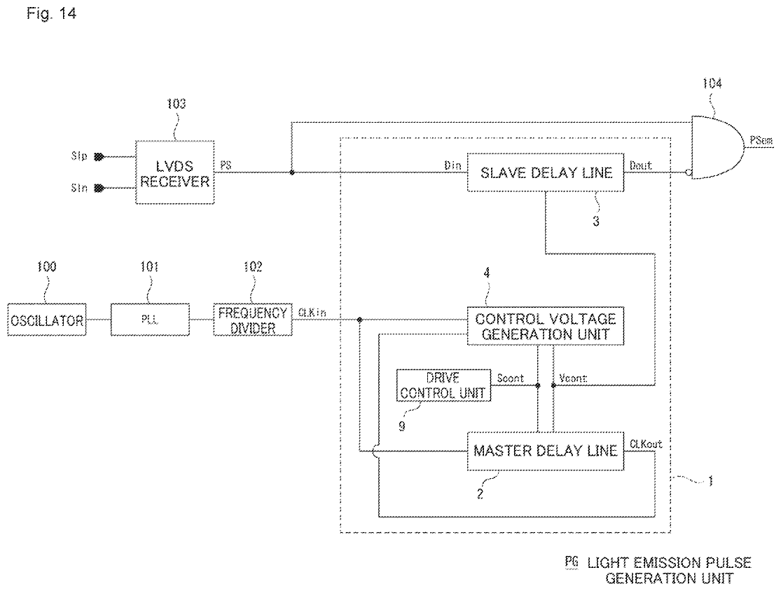

Specifically, a light emission pulse generation unit PG including the DLL circuit 1 will be described with reference to FIG. 14.

The light emission pulse generation unit PG generates a pulse signal for light emission to be supplied to the light emission unit in dToF. This pulse signal is referred to as a light emission pulse signal PSem.

The light emission pulse generation unit PG includes an oscillator 100, a PLL (Phase Locked Loop) 101, a frequency divider 102, an LVDS (Low Voltage Differential Signaling) receiver 103, an AND circuit 104, and a DLL circuit 1.

The oscillator 100 includes, for example, a crystal oscillator that generates oscillation by utilizing the piezoelectric effect of crystal. A high-frequency signal output from the oscillator 100 is synchronized by the PLL 101, divided by the frequency divider 102, and input to the DLL circuit 1 as an input clock signal CLKin.

In the DLL circuit 1, as described above, the master delay line 2 is adjusted so as to provide a reference delay based on the input clock signal CLKin. In the slave delay line 3, an arbitrary delay based on the reference delay is provided to the input data signal Din.

The LVDS receiver 103 receives laser pulse control signals Slp and Sln, which are differential signals, and generates a reference pulse signal PS. The reference pulse signal PS is used to generate a light emission pulse signal PSem to be supplied to the light-emitting unit.

Specifically, the reference pulse signal PS output from the LVDS receiver 103 is input to the AND circuit 104. Further, a signal (the above-mentioned output data signal Dout) obtained by delaying the reference pulse signal PS by the slave delay line 3 is inverted and input to the AND circuit 104.

The AND circuit 104 performs a logical operation on the reference pulse signal PS and the inverted output data signal Dout, and outputs the light emission pulse signal PSem.

A light-emitting unit (not shown) provided at the subsequent stage of the light emission pulse generation unit PG performs pulsed light emission based on the light emission pulse signal PSem.

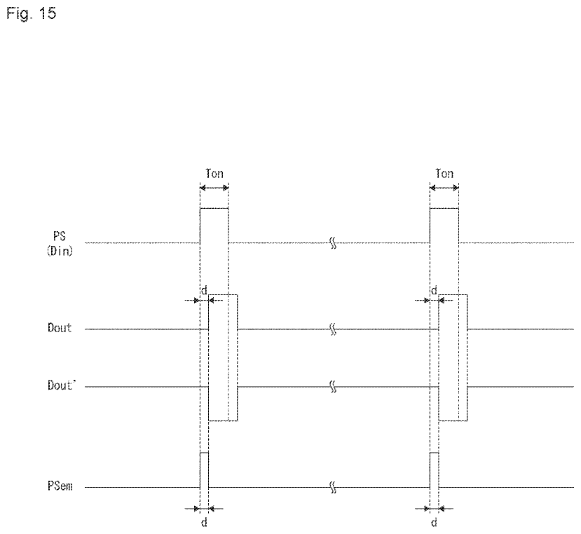

FIG. 15 shows the relationship between the reference pulse signal PS, the delay signal (output data signal Dout) output from the slave delay line 3, and the light emission pulse signal PSem.

The output data signal Dout output from the slave delay line 3 is a signal delayed by a time d with respect to the reference pulse signal PS having a width Ton.

As shown in the figure, the light emission pulse signal PSem output from the AND circuit 104 to which the inverted signal Dout′ of the output data signal Dout and the reference pulse signal PS are input is a pulse signal with a width d.

In other words, the shorter the delay provided by the slave delay line 3, the shorter the width of the light emission pulse signal PSem.

The DLL circuit 1 (1A, 1B, 1C) can be used to generate light emission pulse signals of not only dToF but also iToF (indirect ToF).

In addition, the DLL circuit 1 (1A, 1B, 1C) described above can be used as a DLL included in various memory products such as SDRAM (Synchronous Dynamic Random Access Memory) of DDR (Double Data Rate) standard.

### 9. Summary

As described in the various embodiments, the DLL circuit 1 (1A, 1B, 1C) includes: a first delay line (master delay line 2, 2A, 2B) having a first delay buffer (delay buffer DB) that provides a delay corresponding to the control voltage Vcont to the input clock signal CLKin and configured to output an output clock signal CLKout via the first delay buffer; the control voltage generation unit 4 having the phase comparator 8 that compares the phases of the input clock signal CLKin and the output clock signal CLKout and configured to generate a control voltage Vcont based on the output (control signals Vup, Vdown) of the phase comparator 8; a charge storage unit (capacitor Clpf) in which charge for holding the control voltage Vcont are stored; and the drive control unit 9 configured to output a drive control signal Scont for stopping the operation of the phase comparator 8 based on the determination result regarding the delay-locked state. With the above configuration, the control voltage Vcont, which determines the delay time in the DLL circuit 1, can be held at the voltage value VI in the delay-locked state, and by stopping the operation of the phase comparator 8, the power consumption can be reduced while providing a predetermined delay to the input signal (input clock signal CLKin).

In this way, the running cost of an electronic device equipped with the DLL circuit 1 can be reduced. Furthermore, when the electronic device is equipped with a battery or the like, the operating time of the electronic device can be extended.

Further, in the dynamic hold state, it is possible to stop the supply of the input clock signal CLKin to the phase comparator 8 and the master delay line 2. In this way, the degree of freedom in designing the generation block of the input clock signal CLKin can be improved.

As described with reference to FIG. 7, the drive control unit 9 may determine that the delay-locked state is created when a first time TI has elapsed since the start of the delay lock control. In this way, there is no need to provide a circuit for monitoring the control voltage Vcont, a circuit for comparing voltages, and the like, and the circuit scale of the DLL circuit 1 can be kept small.

As described above, the drive control unit 9 may determine that the delay-locked state is created when the difference between the control voltage Vcont and the target voltage (voltage value V1) becomes less than a predetermined value.

By determining whether or not the delay-locked state is created on the basis of the difference between the control voltage Vcont and the target voltage, it is possible to prevent determination errors.

As described with reference to FIG. 2 and the like, the control voltage generation unit 4 may include the charge pump circuit 6 that performs current control according to the output of the phase comparator 8, and the drive control unit 9 may stop the operation of the charge pump circuit 6 based on the determination result of the delay-locked state.

In this way, power consumption in the DLL circuit 1 can be further reduced.

As described with reference to FIG. 2 and the like, the drive control unit 9 may stop the operation of the first delay line (master delay line 2, 2A, 2B) based on the determination result of the delay-locked state.

In this way, power consumption in the DLL circuit 1 can be further reduced.

As described with reference to FIG. 7 and the like, the drive control unit 9 may restart the operation of the phase comparator 8 according to a predetermined condition being established after stopping the operation of the phase comparator 8.

In this way, it is possible to prevent the control voltage Vcont from deviating too much from the target voltage (voltage value V1) due to the leakage component, and the accuracy of the delay time from decreasing too much.

As described above, the predetermined condition may be the elapse of a second time T2.

This eliminates the need to provide a circuit for monitoring voltage values and the like.

As described above, the predetermined condition may be that the absolute value of the control voltage Vcont is lower than a predetermined voltage (voltage value V2).

In this way, it is possible to prevent the control voltage Vcont from falling too low or rising too much.

As described with reference to FIG. 2 and the like, the charge storage unit may hold charges using the capacitor Clpf included in the low-pass filter 7.

For example, by increasing the capacitance value of the capacitor Clpf included in the low-pass filter 7, it can also function as a charge storage unit.

Since the capacitor Clpf included in the low-pass filter 7 functions as a charge storage unit, it is possible to reduce the number of electronic components and reduce costs.

As described with reference to FIGS. 1 and 2, and the like, the DLL circuit 1 (1A, 1B, 1C) may further include a second delay line (slave delay line 3) having a second delay buffer (delay buffer DB) that provides a delay corresponding to the control voltage Vcont to the input data signal Din, and configured to output an output data signal Dout via the second delay buffer.

By providing the slave delay line 3, it is possible to provide a predetermined delay to the input data signal Din other than the input clock signal CLKin.

Therefore, the DLL circuit 1 can be used for various purposes.

As described in the second embodiment, in the DLL circuit 1A, the first delay line (master delay line 2) may include a plurality of the first delay buffers (delay buffers DB), the first delay line may output an output data signal Dout via N first delay buffers, and the output clock signal CLKout may be a signal output via M first delay buffers different from the N delay buffers. In this way, a signal obtained by delaying the input clock signal CLKin can be output. Further, there is no need to provide the slave delay line 3, and the circuit scale can be kept small.

As described in the third embodiment and the fourth embodiment, the DLL circuit 1B or IC may further include a selector SEL configured to switch between the input clock signal CLKin and the input data signal Din, the first delay line (master delay line 2B) may include a plurality of the first delay buffers (delay buffers DB), the first delay line may output the output clock signal CLKout via M first delay buffers when the input clock signal CLKin is selected by the selector SEL, and the first delay line may output an output data signal Dout via N first delay buffers different from the M first delay buffers when the input data signal Din is selected by the selector SEL.

That is, since the master delay line 2B has the functions of the slave delay line 3 in the first embodiment, it is possible to reduce the number of electronic components constituting the slave delay line 3, whereby the costs and the size of the circuit can be reduced.

Further, by using a common delay line, it is no longer necessary to consider variations in characteristics between the master delay line 2 and the slave delay line 3, and it is possible to improve the precision of delay time.

Furthermore, since one of the two signals (input clock signal CLKin and input data signal Din) input to the DLL circuit 1B or IC is selected by the selector SEL, there is no need to take care of interference between the two signals and the degree of freedom in circuit design can be improved.

As described in the fourth embodiment, in the DLL circuit 1C, the number N may be a number larger than the number M, and the DLL circuit may further include the additional delay line 10 including at least (N-M) first delay buffers (delay buffers DB1′ to DBM′).

In this way, a delay amount larger than the delay amount provided to the input clock signal CLKin can be provided to the input data signal Din.

Therefore, the DLL circuit 1C can be used in a wide variety of situations.

As described in the fourth embodiment, the drive control unit 9 may stop the operation of the phase comparator 8 in a state in which the input data signal Din is selected by the selector SEL. In this way, the power consumption of the DLL circuit 1C can be reduced in a state where a predetermined amount of delay is provided to the input data signal Din.

Various examples can be considered as electronic devices equipped with the above-mentioned DLL circuit 1 (1A, 1B, 1C). For example, the DLL circuit 1 may be provided to generate a light emission pulse signal PSem used for light emission control of a light-emitting device. That is, the light-emitting device includes: a light-emitting unit; and a light emission pulse generation unit PG configured to generate a light emission pulse signal PSem to be supplied to the light-emitting unit and having the DLL circuit 1, wherein the DLL circuit 1 includes: a first delay line (master delay line 2, 2A, 2B) having a first delay buffer (delay buffer DB) that provides a delay corresponding to the control voltage Vcont to the input clock signal CLKin and configured to output an output clock signal CLKout via the first delay buffer; the control voltage generation unit 4 having the phase comparator 8 that compares the phases of the input clock signal CLKin and the output clock signal CLKout and configured to generate a control voltage Vcont based on the output of the phase comparator 8; a charge storage unit (capacitor Clpf) in which charge for holding the control voltage Vcont are stored; and the drive control unit 9 configured to output a drive control signal Scont for stopping the operation of the phase comparator 8 based on the determination result regarding the delay-locked state.

In such a light-emitting device, various effects described above can be obtained.

Note that the effects described in this specification are merely examples and are not limiting, and other effects may also exist.

Moreover, the above-mentioned examples may be combined in any way, and even when various combinations are used, it is possible to obtain the various effects described above.

### 10. Present Technology

The present technology can also adopt the following configuration.

(1)

A DLL circuit including:
a first delay line having a first delay buffer that provides a delay corresponding to a control voltage to an input clock signal, and configured to output an output clock signal via the first delay buffer;
a control voltage generation unit having a phase comparator that compares phases of the input clock signal and the output clock signal, and configured to generate the control voltage based on an output of the phase comparator;
a charge storage unit configured to store charges for holding the control voltage; and a drive control unit configured to output a drive control signal for stopping an operation of the phase comparator based on a determination result regarding a delay-locked state.
   (2)

The DLL circuit according to (1), wherein
the drive control unit determines that the delay-locked state is created when a first time has elapsed since the start of delay lock control.
   (3)

The DLL circuit according to (1), wherein
the drive control unit determines that the delay-locked state is created when a difference between the control voltage and a target voltage is less than a predetermined value.
   (4)

The DLL circuit according to any one of (1) to (3), wherein
the control voltage generation unit includes a charge pump circuit configured to perform current control according to the output of the phase comparator, and
the drive control unit stops an operation of the charge pump circuit based on a determination result of the delay-locked state.
   (5)

The DLL circuit according to any one of (1) to (4), wherein
the drive control unit stops the operation of the first delay line based on a determination result of the delay-locked state.
   (6)

The DLL circuit according to any one of (1) to (5), wherein
the drive control unit restarts the operation of the phase comparator according to a predetermined condition being established after stopping the operation of the phase comparator.
   (7)

The DLL circuit according to (6), wherein
the predetermined condition is the elapse of a second time.
   (8)

The DLL circuit according to (6), wherein
the predetermined condition is that an absolute value of the control voltage is lower than a predetermined voltage.
   (9)

The DLL circuit according to any one of (1) to (8), wherein
the charge storage unit holds charges using a capacitor included in the low-pass filter.
   (10)

The DLL circuit according to any one of (1) to (9), further including:
a second delay line having a second delay buffer that provides a delay corresponding to the control voltage to the input data signal, and configured to output an output data signal via the second delay buffer.
   (11)

The DLL circuit according to any one of (1) to (4) and (6) to (9), wherein
the first delay line includes a plurality of the first delay buffers,
the first delay line outputs an output data signal via N first delay buffers, and
the output clock signal is a signal output via M first delay buffers different from the N delay buffers.
   (12)

The DLL circuit according to any one of (1) to (4) and (6) to (9), further including:
a selector configured to switch between the input clock signal and the input data signal, wherein the first delay line includes a plurality of the first delay buffers,
the first delay line outputs the output clock signal via M first delay buffers when the input clock signal is selected by the selector, and
the first delay line outputs an output data signal via N first delay buffers different from the M first delay buffers when the input data signal is selected by the selector, with the N and the M being natural numbers.
   (13)

The DLL circuit according to (12), wherein
the number N is a number larger than the number M,
the DLL circuit further includes an additional delay line including at least (N-M) first delay buffers.
   (14)

The DLL circuit according to any of (12) and (13), wherein
the drive control unit stops the operation of the phase comparator in a state in which the input data signal is selected by the selector.
   (15)

A light-emitting device including:
a light-emitting unit; and
a light emission pulse generation unit configured to generate a light emission pulse signal to be supplied to the light-emitting unit and having a DLL circuit, wherein
   the DLL circuit includes:
a first delay line having a first delay buffer that provides a delay corresponding to a control voltage to an input clock signal and configured to output an output clock signal via the first delay buffer;
a control voltage generation unit having a phase comparator that compares phases of the input clock signal and the output clock signal, and configured to generate the control voltage based on an output of the phase comparator;
a charge storage unit configured to store charges for holding the control voltage; and
a drive control unit configured to output a drive control signal for stopping an operation of the phase comparator based on a determination result regarding a delay-locked state.

### REFERENCE SIGNS LIST

1, 1A, 1B, 1C DLL circuit
2, 2A, 2B Master delay line (1st delay line)
3 Slave delay line (second delay line)
4 Control voltage generation unit
6 Charge pump circuit
7 Low-pass filter
8 Phase comparator
9 Drive control unit
10 Additional delay line
DB1, DB2, DB3, DBM, DB1′, DBM' Delay buffer (first delay buffer)
DB1, DB2, DB3, DBN Delay buffer (second delay buffer)
CLKin Input clock signal
CLKout Output clock signal
Din Input data signal
Dout Output data signal
Vcont Control voltage
Clpf Capacitor (charge storage unit)
Scont Drive control signal
SEL Selector
PG Light emission pulse generation unit
T1 First time
T2 Second time

1. A DLL circuit comprising:
a first delay line having a first delay buffer that provides a delay corresponding to a control voltage to an input clock signal, and configured to output an output clock signal via the first delay buffer;
a control voltage generation unit having a phase comparator that compares phases of the input clock signal and the output clock signal, and configured to generate the control voltage based on an output of the phase comparator;
a charge storage unit configured to store charges for holding the control voltage; and
a drive control unit configured to output a drive control signal for stopping an operation of the phase comparator based on a determination result regarding a delay-locked state.

2. The DLL circuit according to claim 1, wherein
the drive control unit determines that the delay-locked state is created when a first time has elapsed since the start of delay lock control.

3. The DLL circuit according to claim 1, wherein
the drive control unit determines that the delay-locked state is created when a difference between the control voltage and a target voltage is less than a predetermined value.

4. The DLL circuit according to claim 1, wherein
the control voltage generation unit includes a charge pump circuit configured to perform current control according to the output of the phase comparator, and
the drive control unit stops an operation of the charge pump circuit based on the determination result of the delay-locked state.

5. The DLL circuit according to claim 1, wherein
the drive control unit stops the operation of the first delay line based on a determination result of the delay-locked state.

6. The DLL circuit according to claim 1, wherein
the drive control unit restarts the operation of the phase comparator according to a predetermined condition being established after stopping the operation of the phase comparator.

7. The DLL circuit according to claim 6, wherein
the predetermined condition is the elapse of a second time.

8. The DLL circuit according to claim 6, wherein
the predetermined condition is that an absolute value of the control voltage is lower than a predetermined voltage.

9. The DLL circuit according to claim 1, wherein
the charge storage unit holds charges using a capacitor included in the low-pass filter.

10. The DLL circuit according to claim 1, further comprising:
a second delay line having a second delay buffer that provides the delay corresponding to the control voltage to the input data signal, and configured to output an output data signal via the second delay buffer.

11. The DLL circuit according to claim 1, wherein
the first delay line includes a plurality of the first delay buffers,
the first delay line outputs an output data signal via N first delay buffers, and
the output clock signal is a signal output via M first delay buffers different from the N delay buffers.

12. The DLL circuit according to claim 1, further comprising:
a selector configured to switch between the input clock signal and the input data signal, wherein the first delay line includes a plurality of the first delay buffers,
the first delay line outputs the output clock signal via M first delay buffers when the input clock signal is selected by the selector, and
the first delay line outputs an output data signal via N first delay buffers different from the M first delay buffers when the input data signal is selected by the selector, with the N and the M being natural numbers.

13. The DLL circuit according to claim 12, wherein
the number N is a number larger than the number M,
the DLL circuit further includes an additional delay line including at least (N-M) first delay buffers.

14. The DLL circuit according to claim 12, wherein
the drive control unit stops the operation of the phase comparator in a state in which the input data signal is selected by the selector.

15. A light-emitting device comprising:
a light-emitting unit; and
a light emission pulse generation unit configured to generate a light emission pulse signal to be supplied to the light-emitting unit and having a DLL circuit, wherein
the DLL circuit includes:
a first delay line having a first delay buffer that provides a delay corresponding to a control voltage to an input clock signal and configured to output an output clock signal via the first delay buffer;
a control voltage generation unit having a phase comparator that compares phases of the input clock signal and the output clock signal, and configured to generate the control voltage based on an output of the phase comparator;
a charge storage unit that stored charges for holding the control voltage; and
a drive control unit configured to output a drive control signal for stopping an operation of the phase comparator based on a determination result regarding a delay-locked state.
